(19) United States
(12) Patent Application Publication
(10) Pub. No.: US 2015/0034976 A1
(43) Pub. Date: Feb. 5, 2015

(54) LED CHIP-ON-BOARD TYPE FLEXIBLE PCB AND FLEXIBLE HEAT SPREADER SHEET PAD AND HEAT-SINK STRUCTURE USING THE SAME

(71) Applicant: LED Folio Corporation, Beverly Hills, CA (US)

(72) Inventor: Steven KIM, Fort Lee, NJ (US)

(73) Assignee: LED FOLIO CORPORATION, Beverly Hills, CA (US)

(21) Appl. No.: 14/100,315

(22) Filed: Dec. 9, 2013

(30) Foreign Application Priority Data
Aug. 2, 2013 (KR) 10201391930

(51) Int. Cl. H01L 33/64

(52) U.S. Cl. CPC H01L 33/641
USPC 257/88

(57) ABSTRACT

A chip-on-board LED structure having multiple of LED dies, includes a flexible heat spreading pad for spreading heat and having a planar area; a top flexible foil on the flexible heat spreading pad; a dielectric layer on the first flexible foil; a flexible metal film on the dielectric layer; and an LED die array mounted on and covering a first area of the flexible metal film, wherein the planar area of the flexible heat spreading pad is at least four times larger than the first area of the flexible metal film.

This invention claims the benefit of Korean Patent Application No. 10-2013-091930 filed in Korea on Aug. 2, 2013, which is hereby incorporated by reference in its entirety.

### BACKGROUND OF THE INVENTION

1. Field of the Invention

Embodiments of the invention relate to LED arrays, and more particularly, a chip-on-board LED on a flexible printed circuit board. Although embodiments of the invention are suitable for a wide scope of applications, it is particularly suitable for a flexible chip-on-board LED with a flexible heat spreader sheet.

2. Discussion of the Related Art

In general, an important aspect of designing LED package module and LED lighting module managing the heat dissipation to protect LED performance. The efficiency and lifetime of an LED are very sensitive to the temperature as is the case in most other semiconductor devices. To dissipate the heat from an LED, an aluminum heat sink is normally used. Inherently, an aluminum heat sink is rigid. The designing of the heat sink area and structure are important in the overall design of LED module package.

FIG. 1 shows the structure of heat dissipation path for the conventional LED package 10. Normally, 1 to 4 LED dies 11 are mounted in the package 10 and connected via wire bonding 12 to the lead frame 13. The package 10 is typically plastic. Phosphorous materials 14 cover the LED die 11 such that the blue light from LED die 11 is converted to a white light. This type of structure is used for light output powers ranging from 0.1 watt to 3 watt. The individual LED chip package 10 is soldered onto a printed circuit board assembly 15. The printed circuit board assembly 15 has a layered structure. The top layer is printed circuit board 19, the second layer is Thermal Interface Materials (TIM) 18, and the third layer is an aluminum heat sink 20.

FIG. 2 shows the individual LED chip 10. FIG. 3 shows the LED module where multiple LED chips 10 soldered on the printed circuit board 19 of an LED lighting module. This type of LED lighting module has an advantage in that each individual LED chip 10 is distributed uniformly over the printed circuit board. However, overall high cost for materials and many numbers of manufacturing steps make such an LED lighting module with individual LED chips 10 more costly.

FIG. 4 is a chip-on-board LED 30. The chip-on-board LED is made by many, for example, 50-200 LED dies 11, mounted on a metal printed circuit board. FIG. 5 is a metal printed circuit board 40, which consists of an aluminum plate, dielectric layer, and conducting copper layer 41. Such a metal printed circuit board 40 is similar to a conventional printed circuit board except the metal printed circuit board 40 also has the base plate of aluminum.

The chip-on-board LED has more light output power over an area compared to the conventional LED lighting module shown in FIG. 3. However, the chip-on-board LED is made on a rigid aluminum metal printed circuit board. Since the chip-on-board LED is made on a rigid aluminum, it cannot be used for a curved surface.

### SUMMARY OF THE INVENTION

Accordingly, embodiments of the invention are directed to a flexible chip-on-board LED having a flexible heat spreader sheet pad that substantially obviates one or more of the problems due to limitations and disadvantages of the related art.

An object of embodiments of the invention is to provide a chip-on-board LED structure made on a flexible printed circuit board.

Another object of embodiments of the invention is to provide flexible heat spreader materials as a replacement for rigid aluminum base plate.

Another object of embodiments of the invention is to provide a flexible chip-on-board LED.

Another object of embodiments of the invention is to provide a flexible heat spreader material as a heat dissipation pad.

Another object of embodiments of the invention is to provide a chip-on-pad flexible printed circuit board that can be applied to a curved surface.

Additional features and advantages of embodiments of the invention will be set forth in the description which follows, and in part will be apparent from the description, or may be learned by practice of embodiments of the invention. The objectives and other advantages of the embodiments of the invention will be realized and attained by the structure particularly pointed out in the written description and claims hereof as well as the appended drawings.

To achieve these and other advantages and in accordance with the purpose of embodiments of the invention, as embodied and broadly described, a chip-on-board LED structure having multiple of LED dies includes: a flexible heat spreading pad for spreading heat and having a planar area; a top flexible foil on the flexible heat spreading pad; a dielectric layer on the first flexible foil; a flexible metal film on the dielectric layer; and an LED die array mounted on and covering a first area of the flexible metal film, wherein the planar area of the flexible heat spreading pad is at least four times larger than the first area of the flexible metal film.

In another aspect, the chip-on-board LED structure having multiple of LED dies, includes: a bottom flexible foil; a flexible heat spreading pad on the bottom flexible foil, the flexible heat spreading having a planar area and for spreading heat in a planar direction; a top flexible foil on the flexible heat spreading pad; a dielectric layer on the top flexible foil; a flexible metal film on the dielectric layer; and an LED die array mounted on and covering a first area of the flexible metal film.

It is to be understood that both the foregoing general description and the following detailed description are exemplary and explanatory and are intended to provide further explanation of embodiments of the invention as claimed.

### BRIEF DESCRIPTION OF THE DRAWINGS

The accompanying drawings, which are included to provide a further understanding of embodiments of the invention and are incorporated in and constitute a part of this specification, illustrate embodiments of the invention and together with the description serve to explain the principles of embodiments of the invention.

FIG. 1 is a cross-sectional view of a conventional LED package chip.

FIG. 2 is a conventional LED package chip.

FIG. 3 shows how a conventional LED packaged chip is used for lighting with each LED chip mounted on a printed circuit board.

FIG. 4 is a conventional chip-on-board LED.

FIG. 5 shows a layered structure of the conventional metal printed circuit board.

FIG. 6 is a chip-on-board LED chip structure on a flexible printed circuit board according to embodiments of the invention.

FIG. 7 shows the flexible property of the flexible chip-on-board LED according to embodiments of the invention.

FIG. 8 is a cross-sectional view of a first exemplary embodiment.

FIG. 9 is a cross-sectional view of a second exemplary embodiment.

FIG. 10 is a cross-sectional view of a third exemplary embodiment.

FIG. 11 is a cross-sectional view of a forth exemplary embodiment.

FIG. 12 shows the flexibility of each foil layer for a flexible printed circuit board.

FIGS. 13a-13c demonstrate the flexing responsiveness of a flexible printed circuit board for a flexible chip-on-board LED.

FIG. 14 shows an aluminum heat sink attached to the flexible chip-on-board LED such that the separation area between the LED area and heat sink is more than 2 times the LED area of the chip-on-board LED.

FIG. 15 shows an aluminum heat sink attached to the flexible chip-on-board LED such that the separation area between the LED area and heat sink is less than 1 times the LED area of the chip-on-board LED.

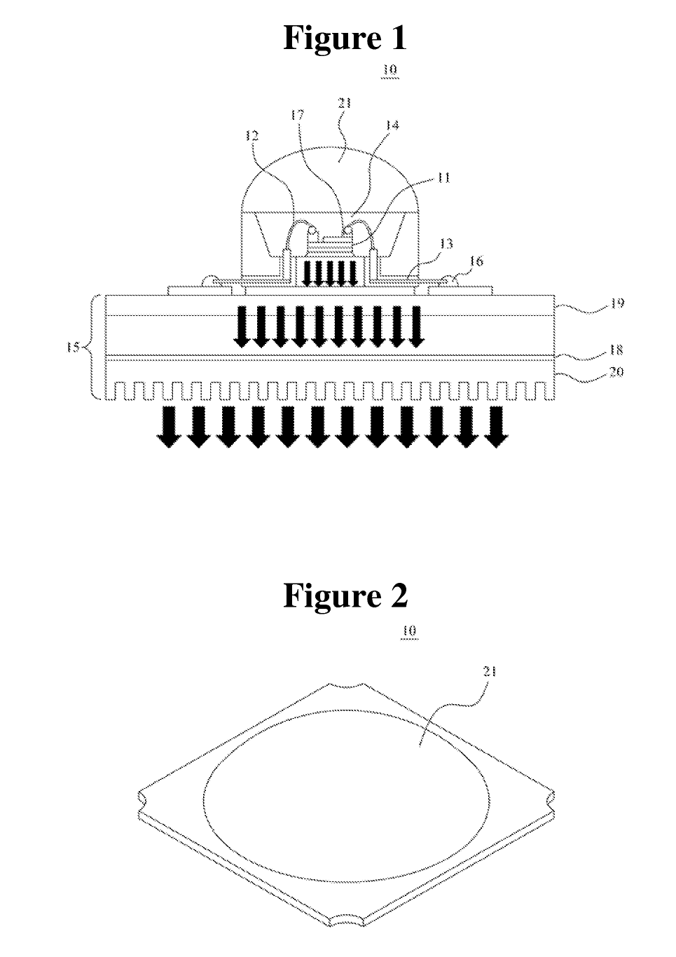

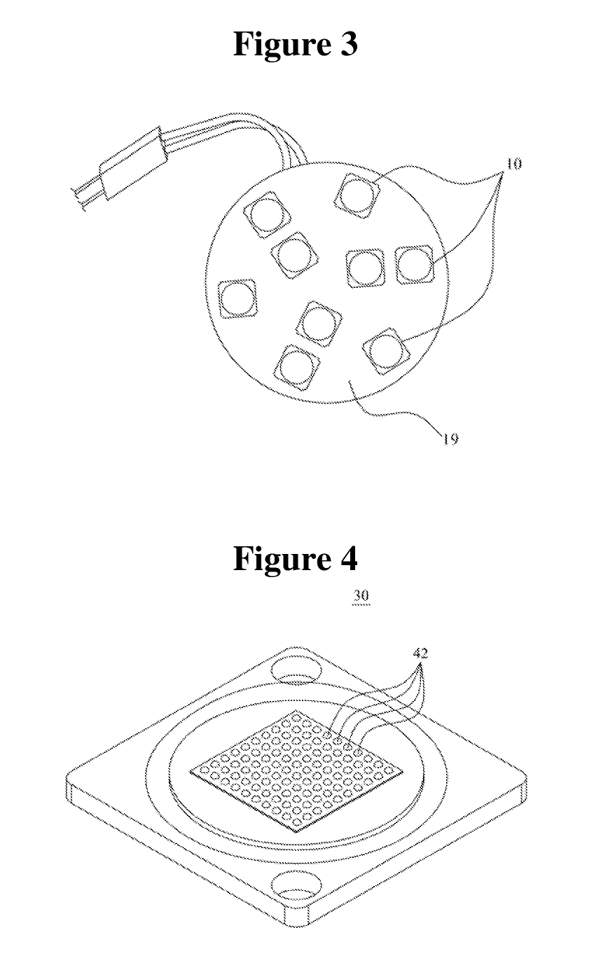

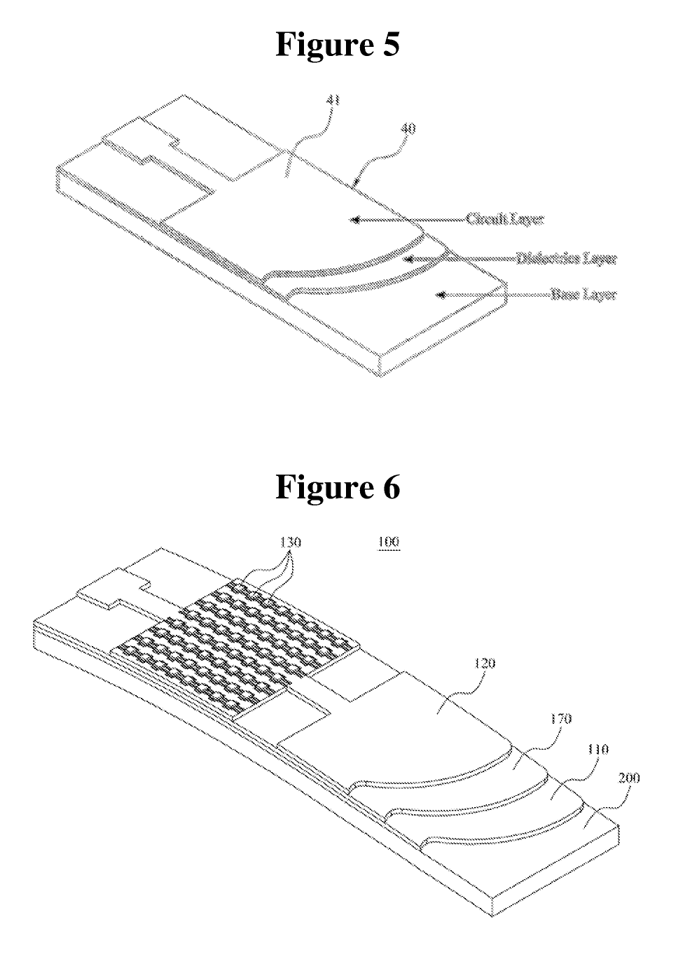

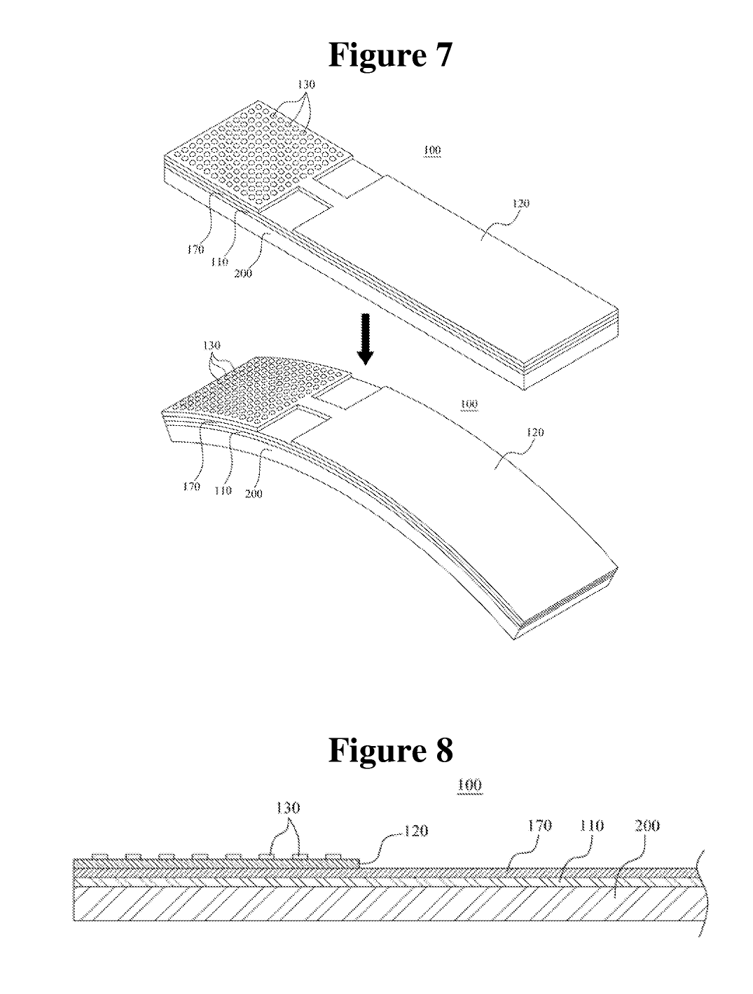

### DETAILED DESCRIPTION OF THE PREFERRED EMBODIMENTS

Reference will now be made in detail to the preferred embodiments of the invention, examples of which are illustrated in the accompanying drawings. Reference will now be made in detail to the preferred embodiments of the invention, examples of which are illustrated in the accompanying drawings. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements.

Embodiments of the invention can use a flexible thin metal foil to improve flexibility and fracture resistance of heat spreader materials. To achieve a flexible chip-on-board, a flexible printed circuit board structure is made with a flexible metal foil. More specifically, a dielectric layer is formed on top of a flexible copper foil so that the dielectric layer can be patterned for an electric circuit to serve as a printed circuit board. To manage heat dissipation, a flexible heat spreader material is used under the copper foil. Unlike the conventional metal printed circuit board, the area where the multiple LEDs are attached is at least ¼ smaller than the area of the total flexible sheet.

FIG. 6 shows the structure of a flexible chip-on-board. Multiple LED dies 130 are attached on top of patterned surface of a first copper layer 120, which can be patterned as in conventional PCB processing. The first copper layer 120 can be formed by one of vapor and liquid phase processes.

A dielectric layer 170 is between the first copper layer 120 and a second copper layer 110. The dielectric layer 170 can be made by coating the first copper layer 120 with a dielectric paint. The second copper layer 110 is formed by a thin flexible copper foil and the thickness can be between 10 um and 30 um. The second copper layer 110 can be bonded to the dielectric paint that forms the dielectric layer 170.

A heat spreading material sheet 200 is coated onto the second copper layer 110. The heat spreading material has a planar thermal conductivity higher than 400 W/mK and the vertical thermal conductivity is less than 10 W/mK. The purpose of using a heat spreading material sheet is to spread the heat across the sheet rather than conduct the heat through the sheet. The heat spreading material is used for spreading heat away from where vertical heat dissipation is not desirable or possible. In a conventional metal PCB, an aluminum plate is used to conduct the heat vertically through the plate. However, such an aluminum plate is rigid and prevents flexibility.

Embodiments of invention have multiple LEDs on top of a flexible printed circuit board to form a flexible chip-on-board LED can be attached and installed on a curved surface while using a heat spreading material in the flexible printed circuit board to move heat from the multiple LEDs so as to effectively dissipate the heat. Thus, more LEDs can be congregated on the flexible chip-on-board LED for intensive light output. The heat spreading material of the flexible chip-on-board LED has a similar thermal conductivity of copper in a planar direction such the heat generated from LEDs can be dissipated effectively away while the sheet remains flexible.

Embodiments of the invention have LEDs mounted on a surface of a flexible printed circuit board with a heat spreader sheet attached to the flexible printed circuit board and a heat sink is mounted on the same surface of the flexible printed circuit board but remotely from the LEDs.

FIG. 8 shows a first exemplary embodiment of layer structure for a flexible chip-on-board LED. As shown on FIG. 8, a flexible metal foil 110 is on a flexible heat spreading pad 200, which is a base layer. The dielectric layer 170, which is for insulating the overlying copper or conducting film 120, is on the dielectric layer 170. The conducting film 120 can be patterned into an appropriate printed circuit connection structure. Multiple LED dies 130 are mounted on a patterned printed circuit connection pattern of the conducting film 120. The overall planar area of the flexible heat spreading pad 200 can be at least 4 times larger than the area of the conducting film 120 covered by the LED dies 130.

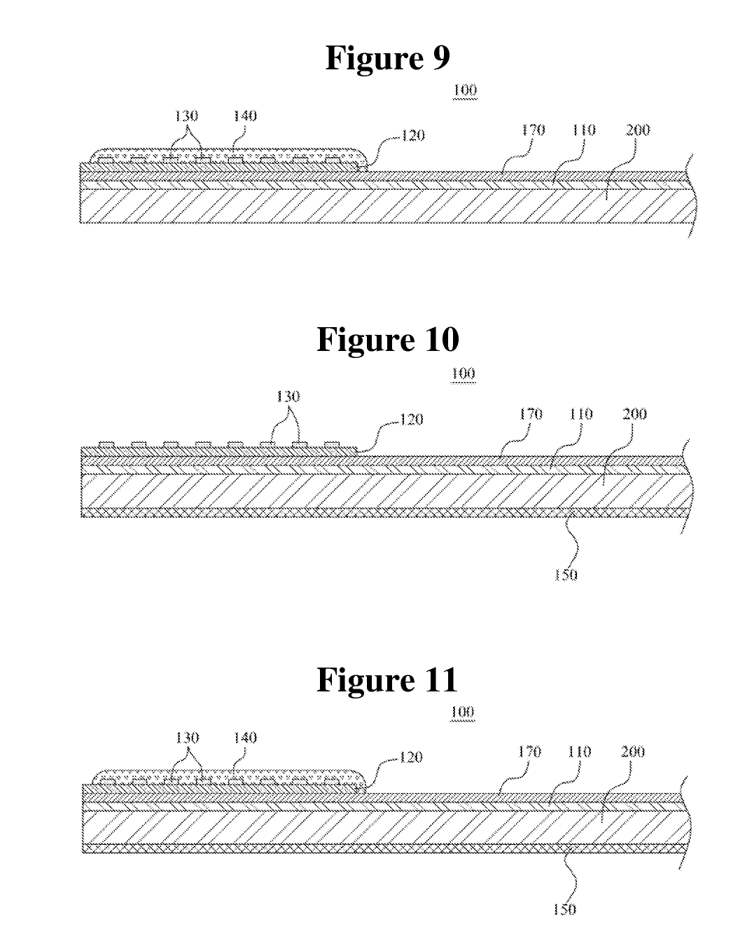

FIG. 9 shows a second exemplary embodiment of a layer structure for a flexible chip-on-board LED. The difference between the first exemplary embodiment and the second exemplary embodiment is the existence of a phosphor layer 140 in the second exemplary embodiment. Thus, the first exemplary embodiment can be used for an RGB-color flexible chip-on-board LED and the second exemplary embodiment is for a white-color flexible chip-on-board LED.

FIG. 10 shows a third exemplary embodiment of a layer structure for a flexible chip-on-board LED. The difference between the third exemplary embodiment and the second exemplary embodiment is an additional flexible foil 150 on the bottom of the heat spreading pad 200 in the third exemplary embodiment. The additional flexible foil 150 provides more reliability because the heat spreading pad's material can be fragile.

FIG. 11 shows a fourth exemplary embodiment of a layer structure of a layer structure for a flexible chip-on-board LED. The difference between the fourth exemplary embodiment and the third exemplary embodiment is the existence of a phosphor layer. Thus, the third exemplary embodiment is an RGB-color flexible chip-on-board LED and the fourth exemplary embodiment is for a white-color flexible chip-on-board LED. The material for the flexible metal foil 110 and the additional metal foil 150 may be either copper or aluminum with a thickness of 10 um to 30 um.

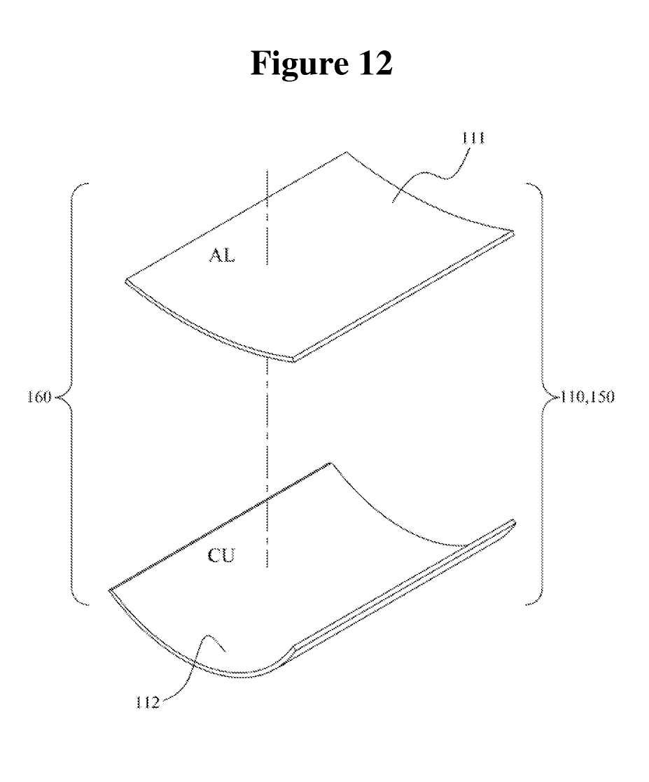

FIG. 12 shows the flexibility of each foil layer for a flexible printed circuit board. FIG. 12 shows the flexibility 160 of the metal foils 110 and 150 in which the top metal foil 111 is aluminum (Al) and the bottom metal foil 112 is copper (Cu). As shown in FIG. 12, the top metal foil 111 flexes with the bottom metal foil 112.

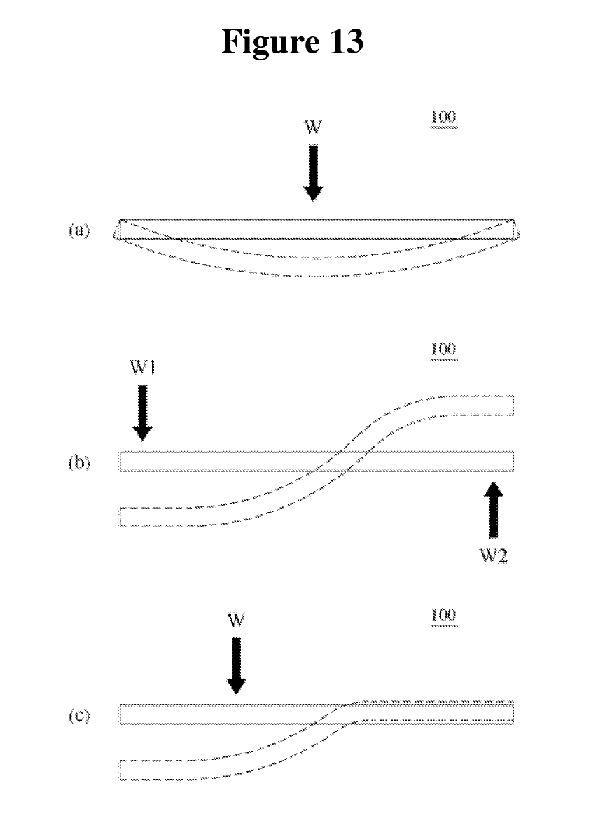

FIGS. 13a-13c demonstrate the flexing responsiveness of a flexible printed circuit board for a flexible chip-on-board LED. As shown in FIG. 13a, a flexible chip-on-board LED 100 should be able to bend in the middle in response to a weight force W in the middle of the flexible chip-on-board LED 100. As shown in FIG. 13b, a flexible chip-on-board LED 100 should be able to warp in response to a weight force W1 at one end of the flexible chip-on-board LED 100 and a weight force W2 at the other end of the flexible chip-on-board LED 100. As shown in FIG. 13c, a flexible chip-on-board LED 100 should be able to bend at the end in response to a weight force W at the end of the flexible chip-on-board LED 100.

The material used in the heat spreading pad 200 should have thermal capabilities and be flexible. In Martin Smalc et als. “Thermal performance of Natural Graphite Heat Spreaders”, a heat spreading pad is defined to have a very high thermal conductivity of above 500 W/mK in a planar direction and a very low thermal conductivity of about 5 W/mK in a vertical direction. The thermal conductivity of aluminum is about 220 W/mK in any direction and the thermal conductivity of copper is about 388 W/mK in any direction. Thus, the planar directional thermal conductivity of a heat spread pad should be higher than that of either aluminum or copper. In an alternative, the heat spreading pad can be a metal coated graphene or another composite of metal and carbon. The heat should quickly spread across the surface of the heat spreading sheet. In embodiments of the invention, the thickness of heat spreading pad can be about 50 um or less. As shown in FIGS. 13a-c, the heat spreading pad with an attached copper foil and can sustain bending.

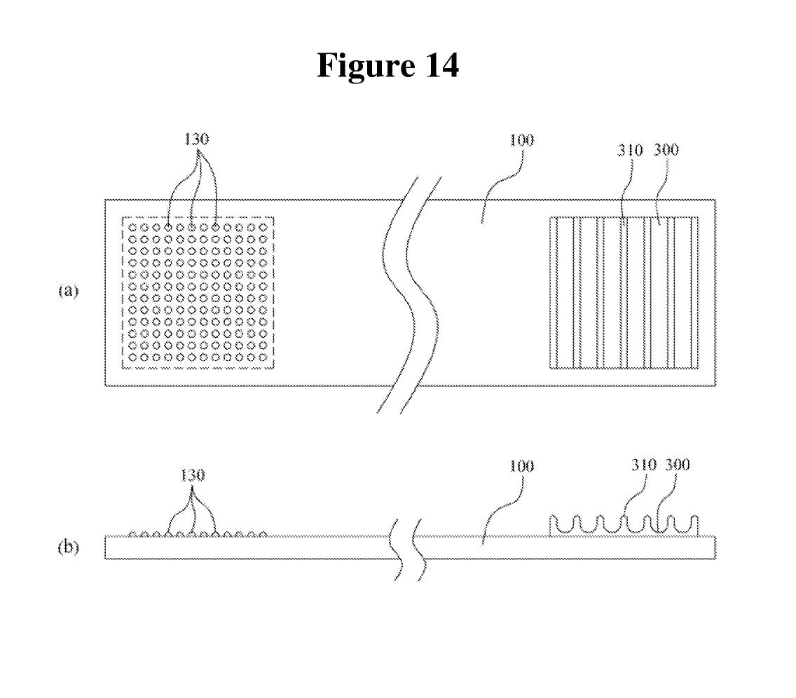

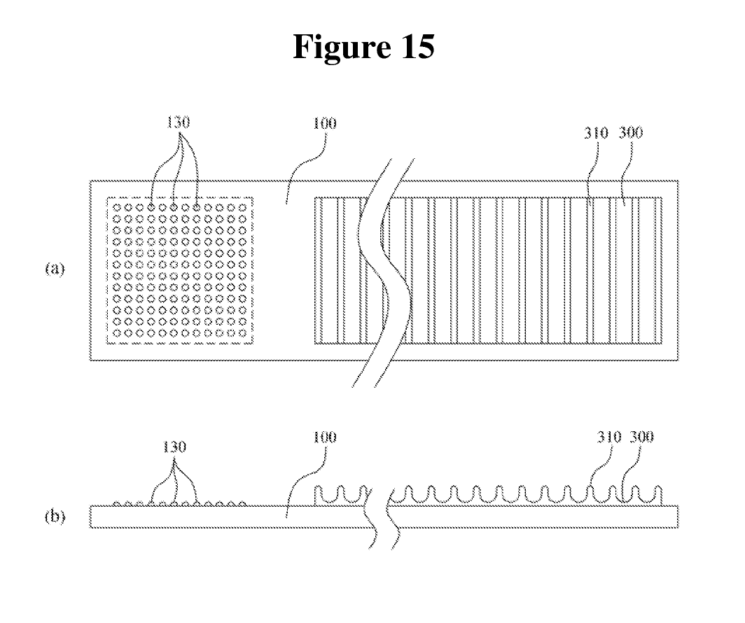

FIG. 14 shows an aluminum heat sink attached to the flexible chip-on-board LED such that the separation area between the LED area and heat sink is more than 2 times the LED area of the chip-on-board LED. FIG. 15 shows an aluminum heat sink attached to the flexible chip-on-board LED such that the separation area between the LED area and heat sink is less than 1 times the LED area of the chip-on-board LED. An LED array 130 is located at one end of the flexible printed circuit board 100 and an aluminum heat sink 300 with fins 310 is located at the other end of the flexible printed circuit board 100. Heat generated by the LED array 130 at one end of the flexible printed circuit board 100 is spread by the flexible printed circuit board 100 by the heat spreader pad across the printed circuit board 100 such that the heat is dissipated to the air by aluminum heat sink 30 on the other end of the flexible printed circuit board 100. The distance between the LED array 130 and the aluminum heat sink 300 can be adjusted depending on the application.

It will be apparent to those skilled in the art that various modifications and variations can be made in the embodiments of the invention without departing from the spirit or scope of the invention. Thus, it is intended that embodiments of the invention cover the modifications and variations of this invention provided they come within the scope of the appended claims and their equivalents.

What is claimed is:

1. A chip-on-board LED structure having multiple of LED dies, comprising:
a flexible heat spreading pad for spreading heat and having a planar area;
a top flexible foil on the flexible heat spreading pad;
a dielectric layer on the first flexible foil;
a flexible metal film on the dielectric layer; and
an LED die array mounted on and covering a first area of the flexible metal film,
wherein the planar area of the flexible heat spreading pad is at least four times larger than the first area of the flexible metal film.

2. The chip-on-board LED structure according to claim 1, wherein the top flexible foil is copper.

3. The chip-on-board LED structure according to claim 1, wherein the flexible heat spreading pad is graphite.

4. The chip-on-board LED structure according to claim 1, wherein the flexible heat spreading pad is a composite of carbon and metal.

5. The chip-on-board LED structure according to claim 1, wherein the flexible metal film is copper.

6. The chip-on-board LED structure according to claim 1, wherein the flexible heat spreading pad has a thickness of about 50 um or less.

7. The chip-on-board LED structure according to claim 1, wherein the heat spreading pad in planar direction has a thermal conductivity greater than 500 W/mK.

8. The chip-on-board LED structure according to claim 1, further comprising a heatsink mounted on and covering a second area of the flexible metal film.

9. The chip-on-board LED structure according to claim 8, wherein a third area of the flexible metal film between the first and second areas of the flexible film is larger than the first area of the flexible metal film.

10. The chip-on-board LED structure according to claim 1, further comprising a bottom flexible foil on the flexible heat spreading pad.

11. A chip-on-board LED structure having multiple of LED dies, comprising:
a bottom flexible foil;
a flexible heat spreading pad on the bottom flexible foil, the flexible heat spreading having a planar area and for spreading heat in a planar direction;
a top flexible foil on the flexible heat spreading pad;
a dielectric layer on the first flexible foil;
a flexible metal film on the dielectric layer; and
an LED die array mounted on and covering a first area of the flexible metal film.

12. The chip-on-board LED structure according to claim 11, wherein the top flexible foil is copper.

13. The chip-on-board LED structure according to claim 11, wherein the flexible heat spreading pad is graphite.

14. The chip-on-board LED structure according to claim 11, wherein the flexible heat spreading pad is a composite of carbon and metal.

15. The chip-on-board LED structure according to claim 11, wherein the flexible metal film is copper.

16. The chip-on-board LED structure according to claim 11, wherein the flexible heat spreading pad has a thickness of about 50 um or less.

17. The chip-on-board LED structure according to claim 11, wherein the flexible heat spreading pad in planar direction has a thermal conductivity greater than 500 W/mK.

18. The chip-on-board LED structure according to claim 11, further comprising a heatsink mounted on and covering a second area of the flexible metal film.

19. The chip-on-board LED structure according to claim 18, wherein a third area of the flexible metal film between the first and second areas of the flexible film is larger than the first area of the flexible metal film.

20. The chip-on-board LED structure according to claim 1, wherein the bottom flexible foil is copper.
